(19) United States
(12) Patent Application Publication
(10) Pub. No.: US 2006/0088967 A1
(43) Pub. Date: Apr. 27, 2006

(54) Finfet transistor process

(75) Inventors: Ching-Nan Hsiao, Kaohsiung Hsien (TW); Ying-Cheng Chuang, Taoyuan Hsien (TW)

Correspondence Address: QUINTERO LAW OFFICE, 1617 BROADWAY, 3RD FLOOR, SANTA MONICA, CA, 90404, US

(73) Assignee: NANYA TECHNOLOGY CORPORATION, TAOYUAN (TW)

(21) Appl. No.: 11/114,735

(22) Filed: Apr. 26, 2005

(30) Foreign Application Priority Data
Oct. 26, 2004 (TW) TW93132344

(51) Int. Cl. H01L 21/336

(52) U.S. Cl. 438/296; 438/299; 438/424

(57) ABSTRACT

The present invention provides a method of manufacturing a FinFET transistor, comprising the steps of: forming a plurality of trenches in a semiconductor substrate, forming a dielectric layer on the semiconductor substrate and filling the trenches, and etching back the dielectric layer to a level below the surface of the substrate to form one or more semiconductor fins standing between the trenches as an active region, such as a source, drain, and channel for the FinFET transistor.

### BACKGROUND OF THE INVENTION

1. Field of the Invention

The invention relates to a method of manufacturing a fin field effect transistor (FinFET), and more particularly to a method of forming a FinFET structure from a bulk semiconductor substrate combined with a shallow trench isolation (STI) process.

2. Description of the Related Art

In the past few decades, reduction in the size of MOSFETs has provided continued improvement in speed performance, circuit density, and cost per unit function. As the gate length of the conventional bulk MOSFET is reduced, transistors with short gate length suffer from problems related to the inability of the gate to substantially control the on and off states of the channel. Phenomena such as reduced gate control associated with transistors with short channel lengths are termed short-channel effects (SCE).

For device scaling well into the sub-30-nm regime, a promising approach to controlling short-channel effects is to use an alternative transistor structure with more than one gate, i.e., multiple-gates. The introduction of additional gates improves the capacitance coupling between the gates and the channel, increases the control of the channel potential by the gate, and helps suppress short-channel scalability of the MOS transistor.

The simplest example of a multiple-gate transistor is the double-gate transistor, as described in U.S. Pat. No. 6,413,802 ('802) issued to Hu, et al. In patent '802, the transistor channel comprises a thin silicon fin formed on an insulator layer, e.g., silicon oxide. Gate oxidation is performed, followed by gate deposition and gate patterning to form a double-gate structure overlying the sides of a fin. Both the source-to-drain direction and the gate-to-gate direction are in the plane of the substrate surface. The body of a FinFET transistor is a vertical fin structure, and the gate of the FinFET is formed on one or more sides of the fin, thereby providing enhanced drive current and improved on and off control functions of the transistor.

FinFET devices must be electrically isolated from each other, and the source and drain of individual devices must be isolated to ensure source to drain decoupling. For this reason, FinFET devices have been typically manufactured from a silicon layer above a buried isolation layer, such as a silicon-on-insulator (SOI) wafer, to provide isolation between fins and between the source and drain region of individual FinFET devices by virtue of the buried isolation layer beneath the fins.

While the use of SOI wafers provides needed isolation for FinFET devices, the most compelling drawback of forming FinFET devices from SOI wafers is the added cost for SOI wafers compared to bulk silicon wafers. Otherwise, the SOI wafers, in which the body of FinFET devices are fabricated, also have problems of floating body effects, larger source/drain parasitic resistance, off-current increase, and low heat transfer rates to the substrate, thus causing deterioration in device performance.

According to the above drawbacks of SOI wafers, U.S. Pat. No. 6,642,090 ('090) provides a method of manufacturing FinFET devices from a bulk semiconductor wafer. In patent '090, vertical fins are first formed from the bulk semiconductor wafer to be active regions, such as sources, drains, and channels, of the FinFET devices. Then, an ion implantation process is performed to damage at least a portion of the semiconductor wafer adjacent the vertical fins, followed by an oxidation process to form an isolation area from the damaged semiconductor wafer portion. Patent '090 provides a method of forming FinFET structures from the bulk semiconductor substrate combined with a shallow trench isolation (STI) process, however, the ion implantation process and the oxidation process parameters must additionally be set.

### SUMMARY OF THE INVENTION

The invention provides a method of manufacturing a fin field effect transistor (FinFET) by combining a FinFET structure manufacturing process with a shallow trench isolation (STI) process.

The invention also provides a method of forming a FinFET device from a bulk semiconductor wafer.

The invention forms a vertical fin as an active region of a FinFET device by combining a FinFET structure manufacturing process with a shallow trench isolation (STI) process, which has the advantages of self-aligned STI structures, without need of an additional specific mask for forming the STI structures, and integrating with current semiconductor manufacturing processes directly.

To achieve these and other advantages, the invention provides a method of manufacturing a fin field effect transistor, comprising: forming a plurality of trenches in a semiconductor substrate, forming a dielectric layer to fill the trenches, and etching back the dielectric layer to a level below the surface of the semiconductor substrate to form one or more semiconductor fins standing between the trenches to be source, drain, and channel active regions of the fin field effect transistor.

### DESCRIPTION OF THE DRAWINGS

For a better understanding of the present invention, reference is made to a detailed description to be read in conjunction with the accompanying drawings, in which:

FIGS. 1A to 1E are cross-sections showing a method of forming a FinFET device known to the inventor;

FIGS. 2A to 2F are cross-sections showing a method of forming a FinFET device according to the invention;

FIGS. 3A and 3B are top views of the structure of FIG. 2B between range A-A′; and

FIG. 4A to 4C are three-dimensional drawings showing a method of forming a FinFET device with the structure of FIG. 2F between range B-B′ according to the invention.

### DETAILED DESCRIPTION OF THE INVENTION

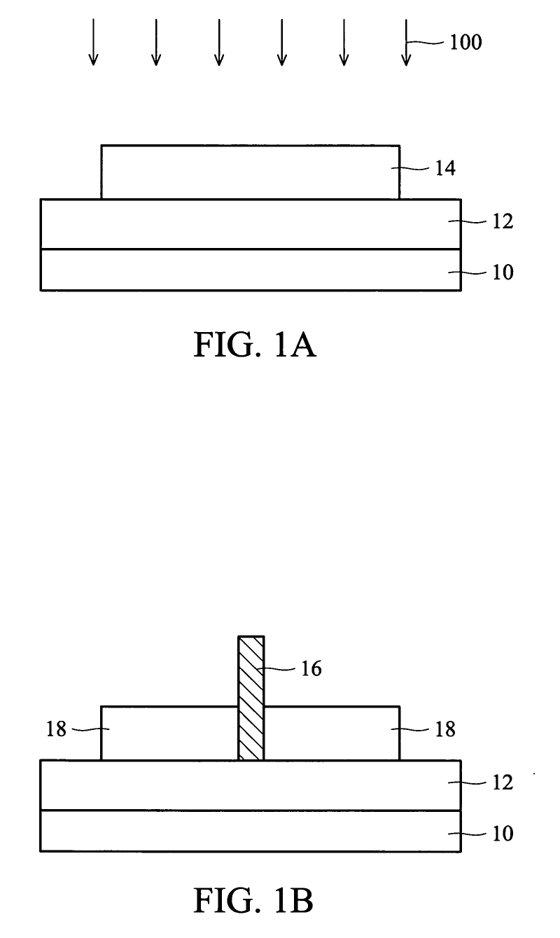

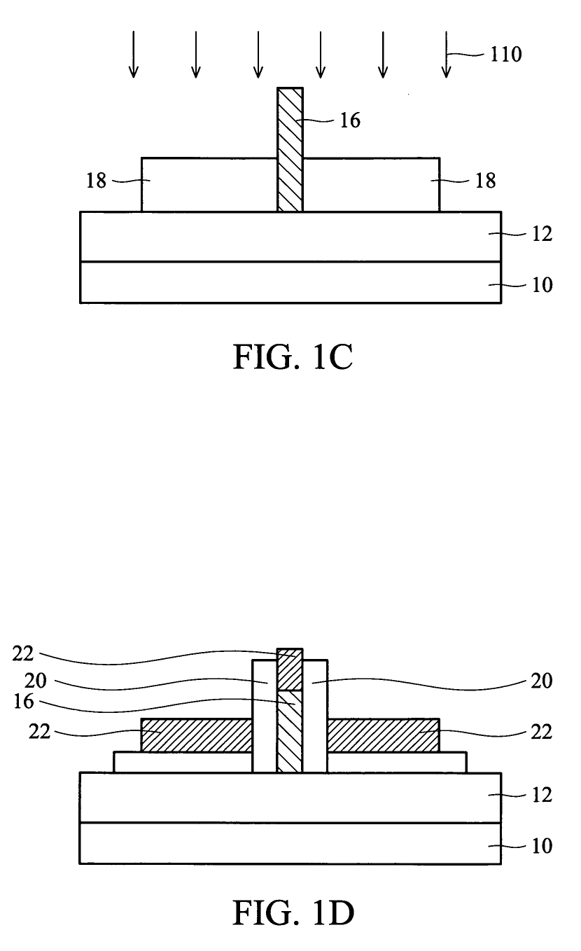

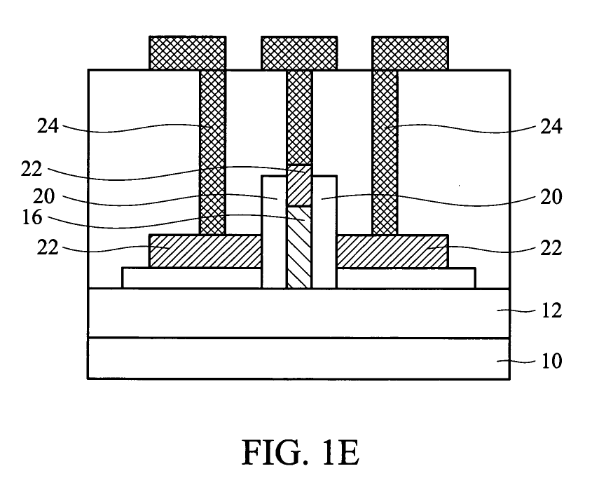

FIGS. 1A to 1E are cross-sections showing a method of forming a FinFET device known to the inventor.

Referring to FIG. 1A, an insulator-on-silicon (SOI) wafer is first provided, which comprises a substrate 10, a buried oxide layer 12, and a silicon layer on the buried oxide layer 12. A silicon fin 14 is formed from the silicon layer by conventional lithographic and etching techniques. Furthermore, an ion implantation process 100 may be performed to adjust the threshold voltages (Vt) of the FinFET device.

A dielectric layer used as a gate dielectric layer is formed covering the silicon fin 14 by oxidizing the silicon fin 14 directly or by other techniques. Then, a gate layer is formed over the dielectric layer. The gate layer may comprise various materials. In this method, the gate layer is preferably a polysilicon layer, and the electrical conductivity thereof may be adjusted by a suitable ion implantation process, such as an in-situ ion implantation process. A gate electrode 16 is then formed from the gate layer by conventional lithographic and etching techniques, and a source/drain region 18 may be formed in the silicon fin 14 oppositely adjacent to the gate electrode 16, as shown in FIG. 1B.

In FIG. 1C, a source/drain extension region is formed by a lightly-doped drain implantation process 110.

Spacers 20 are first formed adjacent to the sidewalls of the gate electrode 16. An ion implantation process may be further performed the source/drain region 18 to provide suitable conductivity. A metal, such as cobalt, is deposited on the polysilicon gate electrode 16 and the source/drain region 18, and silicides 22 are then formed on the top surfaces of the gate electrode 16 and the source/drain region by a self-aligned silicidation process to reduce contact sheet resistances, as shown in FIG. 1D. Contact plug structures 24 are subsequently formed, as shown in FIG. 1E.

FIGS. 1A to 1E show a series of schematic cross-sectional diagrams illustrating a method of forming a FinFET device known to the inventor. This is not related art for the purposes of determining the patentability of the invention. This merely shows a problem found by the inventor. In this method, FinFET devices are formed from a SOI wafer, using the buried oxide layer as an isolation structure. Use of the SOI wafer, however, has the problems of high cost, floating body effects, larger source/drain parasitic resistance, and low heat transfer rates to the substrate, thus causing deterioration of device performance.

Accordingly, the invention provides a method of forming vertical fins of FinFET devices from a bulk semiconductor wafer directly. The bulk semiconductor wafer is preferably a silicon substrate, having advantages of low cost, improved electrical conductivity compared to a silicon layer of a SOI wafer, and better heat transfer rates. Moreover, the invention forms the vertical fins as active regions, such as sources, drains, and channels, of the FinFET devices by combining the FinFET structure manufacturing process with a shallow trench isolation (STI) process, having advantages of self-aligned STI structures, without need of an additional specific mask for forming the STI structures, and integrating with current semiconductor manufacturing processes directly.

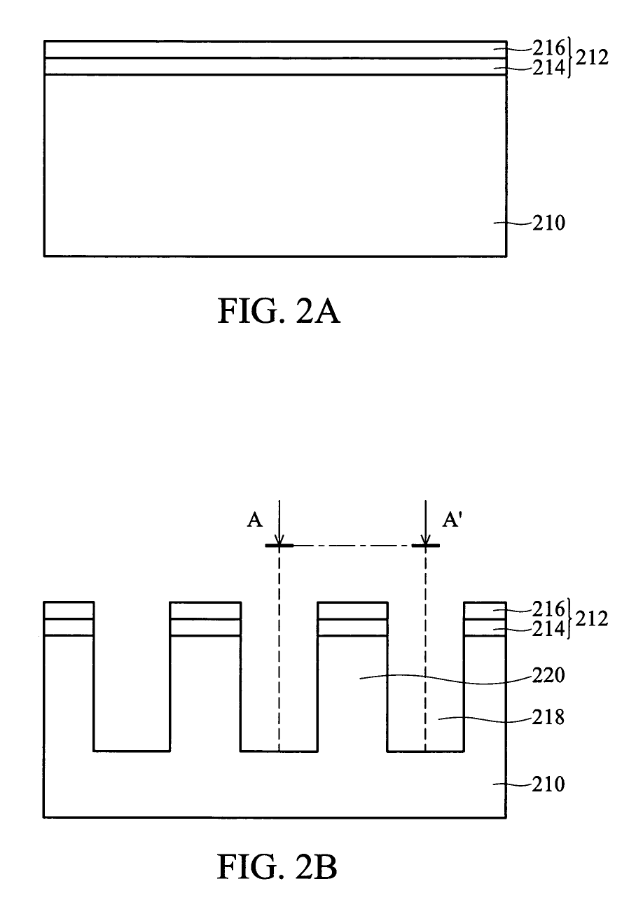

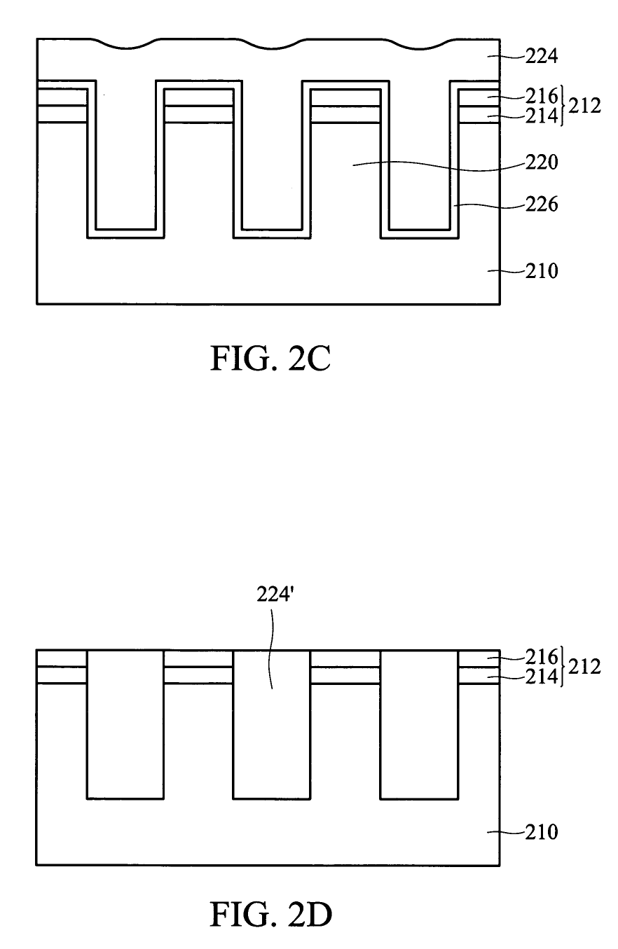

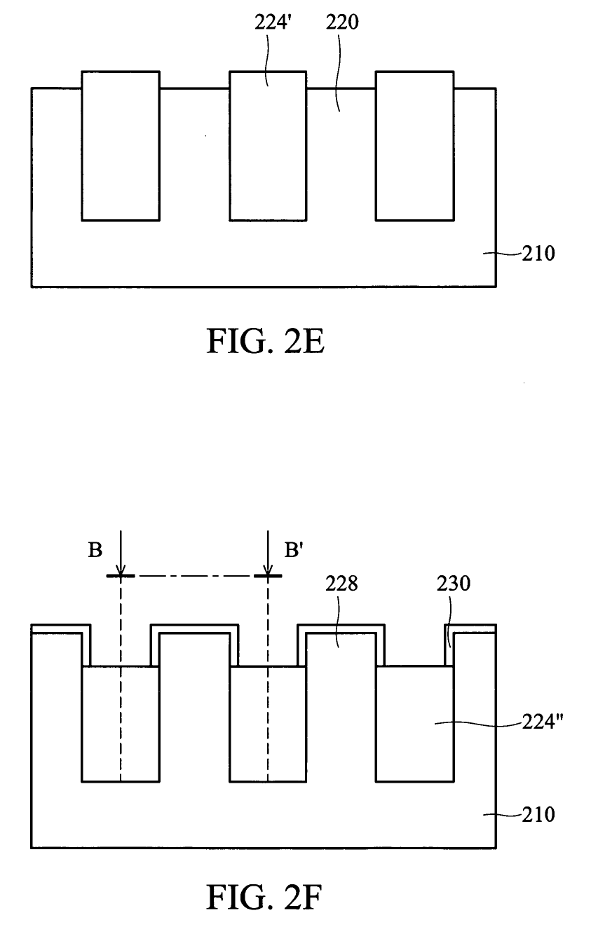

An embodiment of forming the finFET devices from the bulk semiconductor wafer according to the invention combined with the shallow trench isolation (STI) process is described with reference to FIGS. 2A to 2F, FIGS. 3A to 3B, and FIGS. 4A to 4C.

Referring to FIG. 2A, a semiconductor wafer 210 is first provided. In this embodiment, the semiconductor wafer 210 is preferably, but not limited to, a silicon substrate. The semiconductor wafer 210 may also comprise other semiconductor materials, such as a SiGe layer. According to the conventional shallow trench isolation process, a hard mask 212 is then formed on the semiconductor wafer 210. In this embodiment, the hard mask 212 may comprise a pad oxide layer 214 such as silicon oxide, and a pad nitride layer 216 such as silicon nitride. The pad oxide layer 214 may be used to improve adhesion between the pad nitride layer 216 and the semiconductor wafer 210, while the pad nitride layer 216 may be used as a stop layer for chemical mechanical polishing (CMP).

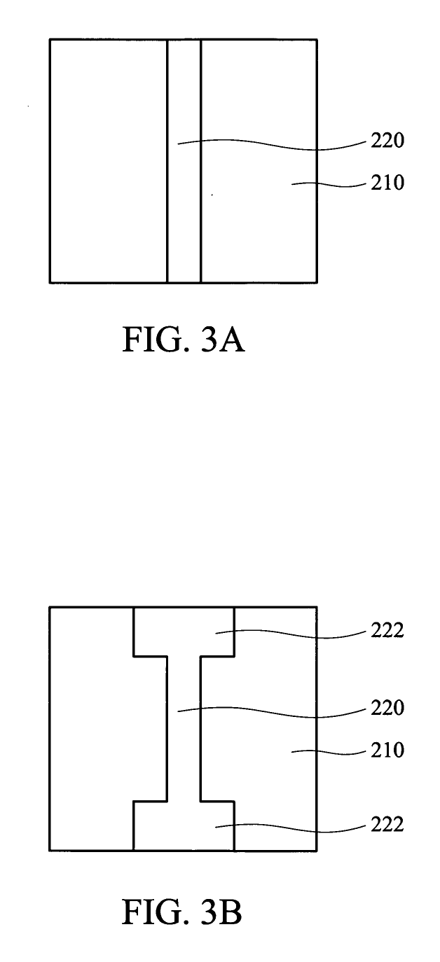

Trenches 218 are patterned by conventional lithographic and etching techniques to define vertical semiconductor fins 220 to be source, drain, and channel active regions of the FinFET devices, as shown in FIG. 2B. FIGS. 3A and 3B are top views of the structure of FIG. 2B between range A-A′. The vertical semiconductor fin 220 of the FinFET device may have source, drain, and channel active regions of the same width, as shown in FIG. 3A, or have source and drain active regions 222 wider than the channel active region, as shown in FIG. 3B. The vertical semiconductor fins 220, the active regions, may have various structures according to requirements, and is not limited to the invention.

A dielectric material 224 is deposited to fill the trenches 218 by performing a chemical vapor deposition process, such as a high-density plasma vapor deposition process (HPCVD), as shown in FIG. 2C. The dielectric material may comprise, but is not limited to, oxide. In this embodiment, the dielectric material 224 may be silicon oxide. Furthermore, a liner layer 226 may be deposited covering the substrate and the trenches 218 before forming the dielectric material 224, thus the adhesion of the subsequent dielectric material 224 is improved. In the embodiment, the liner layer 226 may be silicon oxide.

The dielectric material 224 portion above the hard mask 212 is removed by a chemical mechanical polishing process, such that isolation structures 224′ are level with top surfaces of the trenches, such as shown in FIG. 2D. In this embodiment, both the liner layer 226 and the dielectric material 224 are silicon oxide, such that the liner layer 226 and the dielectric material 224 are merged into the isolation structures 224′, as shown in FIG. 2D.

The hard mask 212 is then removed by a suitable etching process, as shown in FIG. 2E. An ion implantation process may be performed to adjust threshold voltages, using the isolation structures 224′ as a mask. The ion implantation process may comprise ion implantation, plasma immersion ion implantation, solid source diffusion, and any other ion implantation technique. An annealing process may be performed to remove the implantation-induced damage and lattice defects.

Next, the isolation structures 224′ are etched to a level below the top surfaces of the vertical semiconductor fins 220, such that the top surfaces and partial sidewalls of the vertical semiconductor fins 220 are exposed. The exposed vertical semiconductor fins 220 will be used as the source, drain, and channel active regions of the semiconductor fins 228 subsequently. The invention forms the semiconductor fins 228 as active regions of the FinFET devices by combining a FinFET structure manufacturing process with a shallow trench isolation (STI) process, which has advantages of self-aligned STI structures, without need of an additional specific mask for forming the STI structures, and integrating with current semiconductor manufacturing processes directly. The corners of the semiconductor fins 220 may be rounded, rather than sharp as shown in FIG. 2F.

A dielectric layer 230, such as silicon oxide or other suitable material, used as a gate dielectric layer is formed overlying the semiconductor fins 228 by thermal oxidation processes, chemical or physical vapor deposition processes, atomic layer deposition processes, or other suitable technique. In the embodiment, the dielectric layer 230 may preferably be silicon oxide, formed by oxidizing the silicon fins 228 surfaces.

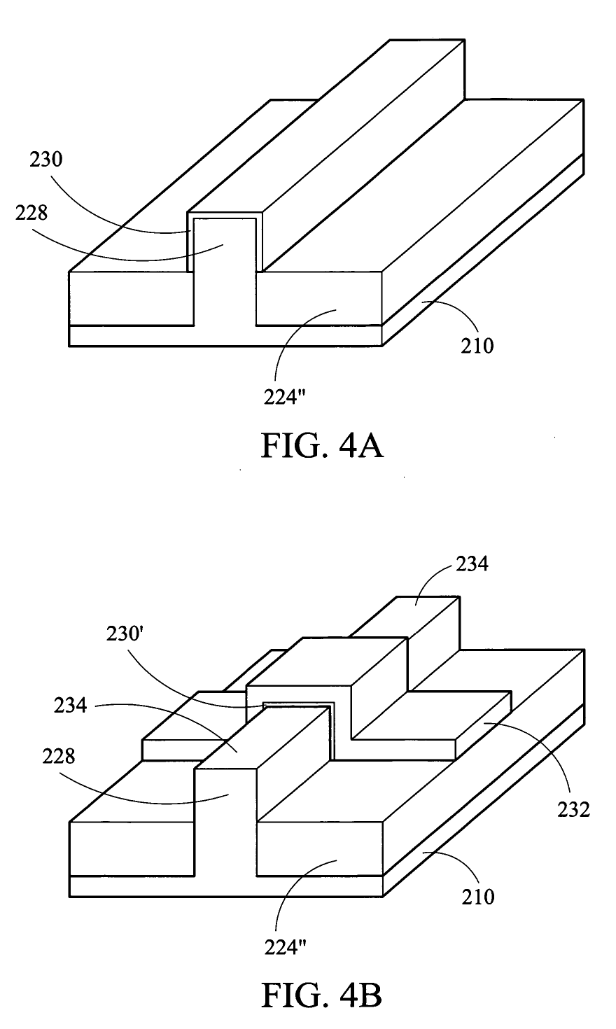

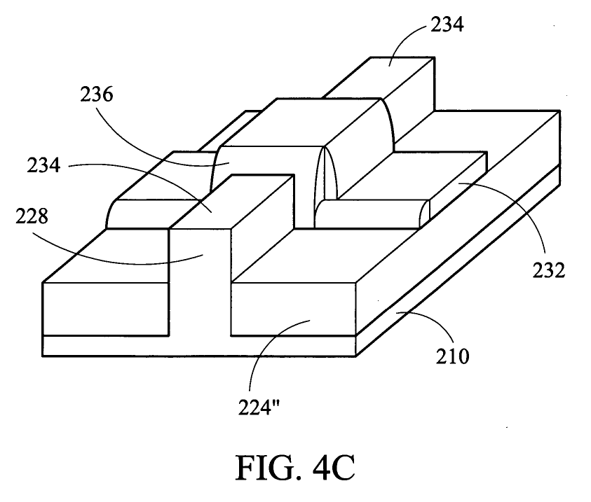

This embodiment of the invention is further illustrated by the vertical semiconductor fin 220 structure of FIG. 3A. FIG. 4A shows a three-dimensional drawing of the structure of FIG. 2F between range B-B′. A gate conductive layer is formed on the dielectric layer 230. The gate conductive layer may comprise any suitable gate material, such as polysilicon, poly-SiGe, refractory metals, metal silicides, other conductive materials, and compositions thereof. The refractory metals may comprise molybdenum, tungsten, and the like. The gate composed of polysilicon or poly-SiGe may have good conductivity adjusted by suitable ion implantation processes. A gate electrode 232 is then formed from the gate conductive layer by conventional lithographic and etching techniques, and the dielectric layer 230 adjacent to the sides of the gate electrode 232 is removed to leave the gate dielectric layer 230′ beneath the gate electrode 232, as shown in FIG. 4B.

Conductivity of a source/drain region 234 may be adjusted by an ion implantation process such as a lightly-doped drain implantation process, such that the off currents are reduced.

Moreover, spacers 236 may be formed on the sidewalls of the gate electrode 232 and the semiconductor fins 228, as shown in FIG. 4C. The spacers may comprise silicon nitride, oxynitride, and silicon oxide. An ion implantation process may then be performed to adjust the conductivity of the source/drain region 234. The ion implantation process may comprise ion implantation, plasma immersion ion implantation, solid source diffusion, and any other ion implantation technique. An annealing process may be performed to remove the implantation-induced damage and lattice defects.

The spacers 236 formed on the sidewalls of the gate electrode 232 and the semiconductor fins 228 may remain, or be removed by suitable etching processes.

A conductive layer may be formed on the surfaces of the source/drain region and the semiconductor fins 228 to reduce contact sheet resistance. The conductive layer may comprise metal silicides such as cobalt silicide formed by a self-aligned silicidation process, metal, polysilicon, epitaxial silicon, and poly-SiGe. The conductivities of the polysilicon, epitaxial silicon, and poly-SiGe may be adjusted by suitable ion implantation processes.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method of manufacturing a fin field effect transistor, comprising:
forming a plurality of trenches in a semiconductor substrate;
forming a dielectric layer to fill the trenches; and
etching back the dielectric layer to a- level below the surface of the semiconductor substrate to form one or more semiconductor fins standing between the trenches to be source, drain, and channel active regions of the fin field effect transistor.

2. The method as claimed in claim 1, wherein the semiconductor substrate comprises a silicon substrate.

3. The method as claimed in claim 1, further comprising forming a chemical mechanical polishing stop layer before forming the trenches in the semiconductor substrate.

4. The method as claimed in claim 1, further comprising performing a chemical mechanical polishing process before etching back the dielectric layer such that the dielectric layer is level with top surfaces of the trenches.

5. The method as claimed in claim 3, further comprising removing the chemical mechanical polishing stop layer after performing a chemical mechanical polishing process.

6. The method as claimed in claim 1, further comprising forming a liner layer before forming the dielectric layer to fill the trenches.

7. The method as claimed in claim 1, further comprising forming a gate dielectric layer covering the semiconductor fins.

8. The method as claimed in claim 7, further comprising forming a gate electrode on the gate dielectric layer.

9. The method as claimed in claim 8, further comprising performing a first implantation process to form a source/drain in the semiconductor fins oppositely adjacent to the gate.

10. The method as claimed in claim 9, wherein the first implantation process comprises a lightly-doped drain implantation process.

11. The method as claimed in claim 10, further comprising forming spacers on the sidewalls of the gate electrode and the semiconductor fins.

12. The method as claimed in claim 11, further comprising performing a second implantation process to adjust the conductivity of the source/drain.

13. The method as claimed in claim 12, further comprising removing the spacers.

14. The method as claimed in claim 1, wherein the source, drain, and channel active regions of the fin field effect transistor have the same width.

15. The method as claimed in claim 1, wherein the source and drain are wider than the channel of the fin field effect transistor.
